(19) United States
(12) Patent Application Publication
(10) Pub. No.: US 2016/0300875 A1
(43) Pub. Date: Oct. 13, 2016

(54) SUBSTRATE SEPARATION-TYPE THREE-DIMENSIONAL CHIP STACKING IMAGE SENSOR AND METHOD FOR MANUFACTURING SAME

(71) Applicant: SILICONFILE TECHNOLOGIES INC., Gyeonggi-do (KR)

(72) Inventors: Jun Ho WON, Gyeonggi-do (KR); Do Young LEE, Gyeonggi-do (KR)

(21) Appl. No.: 15/036,480

(22) PCT Filed: Nov. 11, 2014
(86) PCT No.: PCT/KR2014/010803

§ 371 Date: May 13, 2016

(30) Foreign Application Priority Data
Nov. 13, 2013 (KR) 10-2013-0137856

(51) Int. Cl. H01L 27/146

(52) U.S. Cl. CPC H01L 27/14634; H01L 27/1469; H01L 27/1462; H01L 27/14621; H01L 27/14627; H01L 27/14685; H01L 27/14636

(57) ABSTRACT

The present invention provides relates to a substrate separation-type three-dimensional chip stacking image sensor of which a noise characteristic is improved by separately implementing an image sensor circuit as a first semiconductor chip and a second semiconductor chip and physically separating substrate respectively forming the first semiconductor chip and the second semiconductor chip, and a method for manufacturing the same. The present invention has the advantage that even though a plurality of circuit blocks are formed on one semiconductor substrate, the substrate is physically separated such that the separated substrates independently operate.

### TECHNICAL FIELD

The present invention relates to an image sensor and a method for manufacturing the same, more particularly, to a substrate separation-type three-dimensional chip stacking image sensor and method for manufacturing same that improves a noise characteristic by physically separating each substrate of a first semiconductor chip and a second semiconductor chip after an image sensor circuit is implemented with the first semiconductor chip and the second semiconductor chip.

### BACKGROUND ART

An image sensor having a combined structure where a cell of an image sensor is implemented in a combination of two memory chips, which are stacked, is referred to as a three-dimensional chip stacking image sensor.

In case of a conventional three-dimensional chip stacking image sensor, each substrate of a first chip and a second chip is constituted with one substrate, and a plurality of circuit blocks are formed on a substrate of the first chip and a substrate of the second chip, respectively.

Thus, in case that a bias voltage is differently applied in a same substrate, a characteristic of a unit element of circuit blocks is changed due to an influence on a body effect, and in case that a power supply voltage is different, a power voltage noise may be occur.

Therefore, in general, in order to prevent these noises, an additional well is applied to separate the circuit blocks. However, although this method is used, there are difficulties in removing a power noise and maximizing a characteristic of the circuit blocks.

### DISCLOSURE

### Technical Problem

The present invention is directed to a substrate separation-type three-dimensional chip stacking image sensor and method for manufacturing same that improves a noise characteristic by physically separating each substrate of a first semiconductor chip and a second semiconductor chip and excluding an interference therebetween.

### Technical Solution

In accordance with an embodiment of the present invention, a substrate separation-type three-dimensional chip stacking image sensor may include a first semiconductor chip having a plurality of first element regions, which are formed in a first substrate by block units; and a second semiconductor chip having a plurality of second element regions, which are formed in a second substrate by block unit, the second semiconductor chip is stacked on the first semiconductor chip, and wherein the second semiconductor chip further includes a substrate separation means that separates the plurality of second element regions formed in the second substrate by the block units.

In accordance with another embodiment of the present invention, a substrate separation-type three-dimensional chip stacking image sensor may include a first semiconductor chip having a plurality of first element regions, which are formed in a first substrate by block units; and a second semiconductor chip having a plurality of second element regions, which are formed in a second substrate by block units, wherein the second semiconductor chip is stacked on the first semiconductor chip, and wherein the first semiconductor chip further includes a substrate separation means that separates the plurality of first element regions formed in the first substrate by the block units.

In accordance with another embodiment of the present invention, a substrate separation-type three-dimensional chip stacking image sensor may include a first semiconductor chip having a plurality of first element regions, which are formed in a first substrate by block units; and a second semiconductor chip having a plurality of second element regions, which are formed in a second substrate by block units, wherein the second semiconductor chip is stacked on the first semiconductor chip, wherein the first semiconductor chip further includes a substrate separation means that separates the plurality of first element regions formed in the first substrate by the block units, and wherein the second semiconductor chip further includes a substrate separation means that separates the plurality of second element regions formed in the second substrate by the block units.

In accordance with an embodiment of the present invention, a method for manufacturing a substrate separation-type three-dimensional chip stacking image sensor may include steps of: forming a first semiconductor chip that a plurality of first element regions are formed in a first substrate by block units; forming a second semiconductor chip that a plurality of second element regions are formed in a second substrate by block units; bonding the first semiconductor chip to the second semiconductor chip; and forming a substrate separation means between blocks of the plurality of first element regions formed in the first semiconductor chip or between blocks of the plurality of second element regions formed in the second semiconductor chip.

In accordance with another embodiment of the present invention, a method for manufacturing a substrate separation-type three-dimensional chip stacking image sensor may include steps of: forming a substrate separation means between blocks of a plurality of first element regions to be formed in a first substrate or between blocks of a plurality of second element regions to be formed in a second substrate through a plasma etch or a wet etch; forming a first semiconductor chip that the plurality of first element regions are formed in the first substrate by block units; forming a second semiconductor chip that the plurality of second element regions are formed in the second substrate by block units; and bonding the first semiconductor chip to the second semiconductor chip.

In accordance with another embodiment of the present invention, a method for manufacturing a substrate separation-type three-dimensional chip stacking image sensor may include steps of: forming a first semiconductor chip that a plurality of first element regions are formed in a first substrate by block units and a substrate separation means is formed between blocks of the plurality of first element regions; forming a second semiconductor chip that a plurality of second element regions are formed in a second substrate by block units and a substrate separation means is formed between blocks of the plurality of second element regions; and bonding the first semiconductor chip to the second semiconductor chip.

### Advantageous Effects

As according to a three-dimensional chip stacking image sensor of the present invention, a substrate is independently affected by physically separating the substrate although a plurality of circuit blocks are formed in one semiconductor substrate.

Through this, even if a power voltage of each of circuit blocks is different, an interference does not occur between the circuit blocks, and a characteristic of a unit element formed in each of the circuit blocks may be improved by applying a separate bulk voltage to each of the circuit blocks.

### DESCRIPTION OF DRAWINGS

FIG. 1 is a cross sectional view illustrating a substrate separation-type three-dimensional chip stacking image sensor in accordance with an embodiment of the present invention.

FIG. 2 is a cross sectional view illustrating a substrate separation-type three-dimensional chip stacking image sensor in accordance with another embodiment of the present invention.

FIG. 3 is a cross sectional view illustrating a substrate separation-type three-dimensional chip stacking image sensor in accordance with another embodiment of the present invention.

FIG. 4 is a cross sectional view illustrating a substrate separation-type three-dimensional chip stacking image sensor in accordance with another embodiment of the present invention.

FIG. 5 is a cross sectional view illustrating a filling of a substrate separation means of a substrate separation-type three-dimensional chip stacking image sensor in accordance with another embodiment of the present invention.

FIG. 6 is a flow chart illustrating a process flow of a method of manufacturing a substrate separation-type three-dimensional chip stacking image sensor in accordance with an embodiment of the present invention,

FIG. 7 is a flow chart illustrating a process flow of a method of manufacturing a substrate separation-type three-dimensional chip stacking image sensor in accordance with another embodiment of the present invention.

FIG. 8 is a flow chart illustrating a process flow of a method of manufacturing a substrate separation-type three-dimensional chip stacking image sensor in accordance with another embodiment of the present invention.

### BEST MODE

Hereinafter, various embodiments will be described below in more detail with reference to the accompanying drawings such that a skilled person in this art understand and implement the present invention easily.

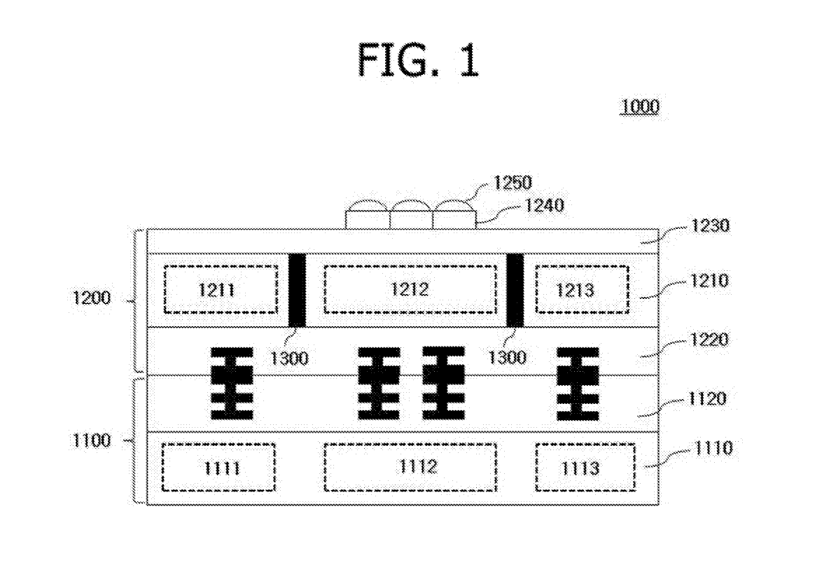

FIG. 1 is a cross sectional view illustrating a substrate separation-type three-dimensional chip stacking image sensor in accordance with an embodiment of the present invention.

Referring to FIG. 1, a substrate separation-type three-dimensional chip stacking image sensor 1000 in accordance with an embodiment of the present invention has a three-dimensional chip stacking structure where a second semiconductor chip 1200 is stacked on a first semiconductor chip 1100.

The first semiconductor chip 1100 includes a first substrate 1110 and a first insulation layer 1120. A plurality of first element regions 1111 to 1113 are formed on the first substrate 1110 by a block unit according to a function of a semiconductor chip. A first metal distribution layer 1121 is formed in the first insulation layer 1120.

The second semiconductor chip 1200 includes a second substrate 1210 and a second insulation layer 1220. A plurality of second element regions 1211 to 1213 are formed on the second substrate 1210 by a block unit according to a function of a semiconductor chip. A second metal distribution layer 1221 is formed in the second insulation layer 12220.

The second semiconductor chip 1200 may further include an anti-reflection layer 1230, a color filter layer 1240 and a micro-lens layer 1250 on an upper surface of the second substrate 1210.

Herein, the second semiconductor chip 1200 includes a substrate separation means 1300 for separating the plurality of second element regions 1211 to 1213 formed on the second substrate 1210 by the block unit.

The substrate separation means 1300 may be implemented with a trench shape by a reactive ion etching (RIE) method or a wet etching method using a plasma.

Herein, the substrate separation means 1300 may be implemented to separate only the second substrate 1210 or to separate the second substrate and a second insulation layer 120 formed on the second substrate 1210.

Like this, by physically and perfectly separating a circuit block and a pixel region formed on the second substrate or separating a plurality of circuit blocks through the substrate separation means 1300, a bulk voltage may be differently applied to the substrate and the circuit blocks may be independently controlled.

For example, the plurality of second element regions 1211 to 1213 formed in the second semiconductor chip 1200 are implemented with a peripheral region and a pixel array including a photodiode, and the plurality of first element regions 1111 to 1113 formed in the first semiconductor chip 1100 may be implemented with a circuit region for converting a charge transmitted from the photodiode into an electrical signal, and outputting a converted electrical signal.

Thus, a charge transfer characteristic may be greatly improved by adjusting a substrate bulk voltage (substrate bias) on the pixel region and having a great potential gradient between the photodiode and the floating node.

However, this is described as one example of the present invention, and the plurality of first element regions 1111 to 1113 and the plurality of second element regions 1211 to 1213 are not restricted in this example, and may be changed variously.

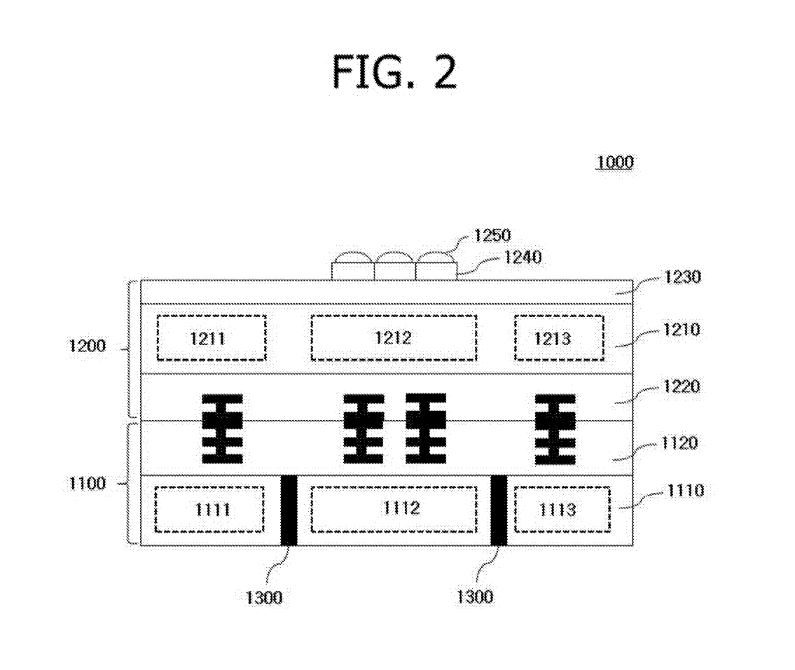

FIG. 2 is a cross sectional view illustrating a substrate separation-type three-dimensional chip stacking image sensor in accordance with another embodiment of the present invention.

Referring to FIG. 2, a substrate separation/type three-dimensional chip stacking image sensor 1000 in accordance with another embodiment of the present invention includes a three-dimensional stacking structure where a second semiconductor chip 1200 is stacked on a first semiconductor chip 1100.

A configuration of the substrate separation-type three-dimensional chip stacking image sensor 1000 shown in FIG. 2 in accordance with another embodiment of the present invention is same as a configuration of the image sensor shown in FIG. 1 except that the substrate separation means 130 is formed in the first semiconductor chip 1100.

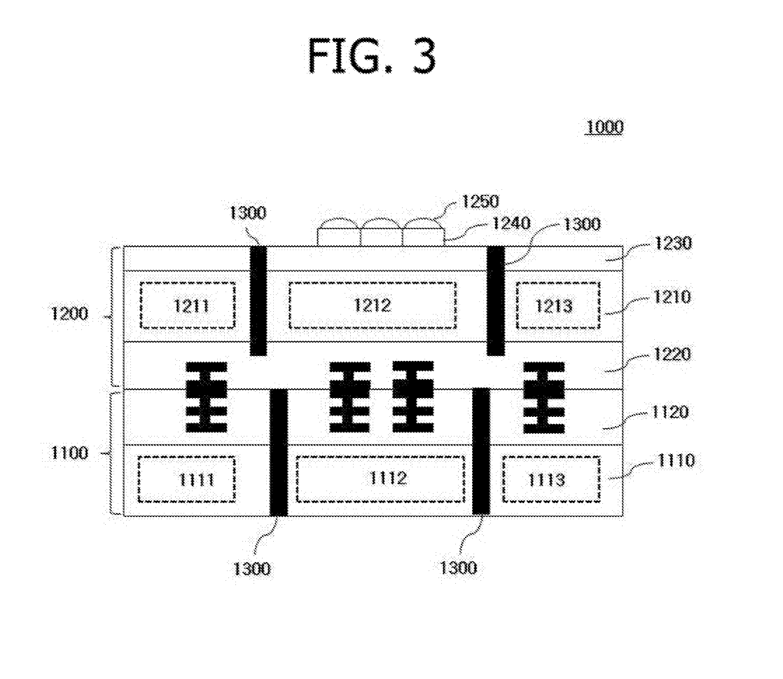

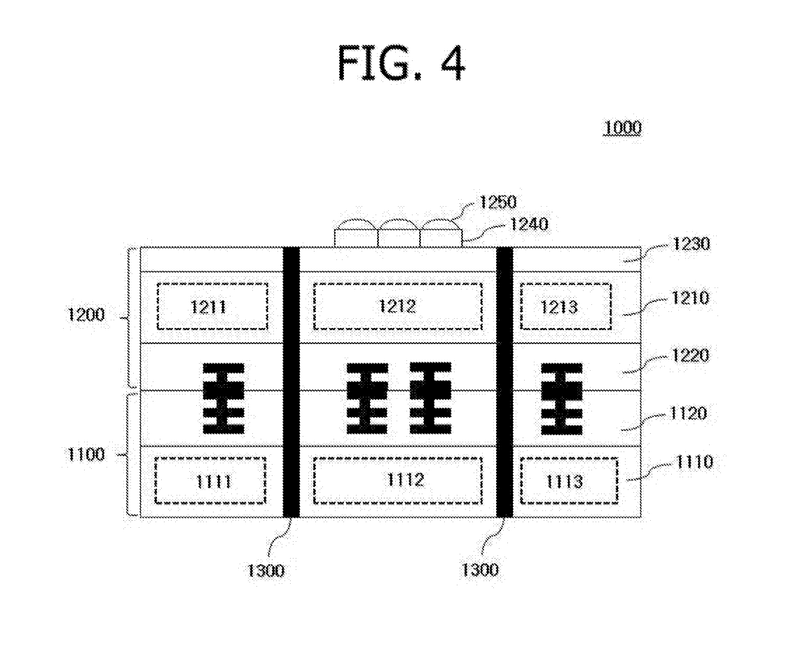

FIGS. 3 and 4 are cross sectional views illustrating a substrate separation-type three-dimensional chip stacking image sensor in accordance with another embodiment of the present invention.

Referring to FIGS. 3 and 4, a substrate separation-type three-dimensional chip stacking image sensor 1000 in accordance with another embodiment of the present invention includes a three-dimensional stacking structure where a second semiconductor chip 1200 is stacked on a first semiconductor chip 1100.

A configuration of the substrate separation-type three-dimensional chip stacking image sensor 1000 shown in FIGS. 3 and 4 in accordance with another embodiment of the present invention is same as a configuration of the image sensor shown in FIGS. 1 and 2 except that the substrate separation means 130 is formed in all of the first semiconductor chip 1100 and the second semiconductor chip 1200.

As shown in FIG. 3, the substrate separation means 1300 formed in the first semiconductor chip 1100 and the substrate separation means 1300 formed in the second semiconductor chip 1200 are separated, and separate the first substrate 1110 and the first insulation layer 1120 and the second substrate 1210 and the second insulation layer 1220, respectively.

Meanwhile, as shown in FIG. 4, in case that the substrate separation means 1300 is formed in an integrated body type through the first semiconductor chip 1100 and the second semiconductor chip 1200, all of the first substrate 1110, the second substrate 1210, the first insulation layer 1120 and the second insulation layer 1220 may be separated.

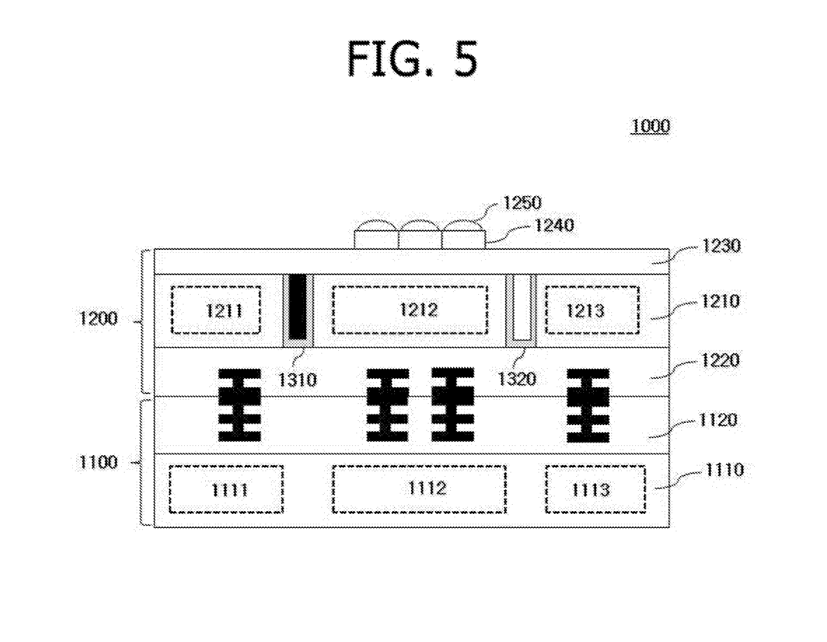

FIG. 5 is a cross sectional view illustrating a filling of substrate separation means of a substrate separation-type three-dimensional chip stacking image sensor in accordance with another embodiment of the present invention.

As shown in FIG. 5, a conductive material of titanium (Ti), titanium nitride (TiN), aluminum (Al), tungsten (W) or poly may be filled in the substrate separation means 1310 which is implemented in a trench shape, and an insulation material such as an oxide layer, a nitride layer or a photoresist of an overcoat material for color filter or a planarization may be filled in the substrate separation means 1310.

Meanwhile, a vacant space may be formed in the trench region of the substrate separation means 1320 without any gap fill material.

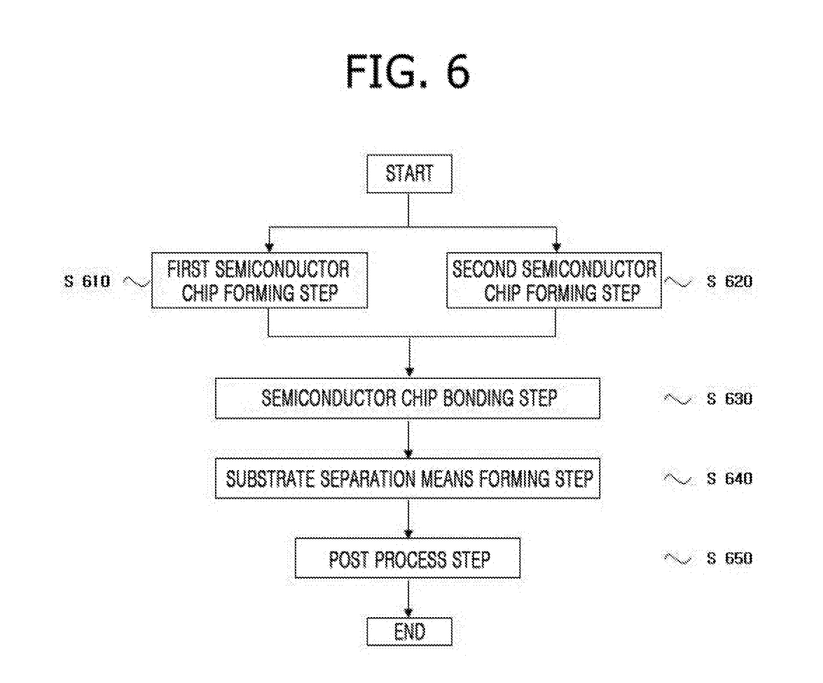

FIG. 6 is a flow chart illustrating a process flow of a method of manufacturing a substrate separation-type three-dimensional chip stacking image sensor in accordance with an embodiment of the present invention.

Referring to FIG. 6, a method of manufacturing a substrate separation-type three-dimensional chip stacking image sensor in accordance with an embodiment of the present invention includes a first semiconductor chip forming step S610, a second chip forming step S620, a semiconductor chip bonding step S630 and a substrate separation means forming step S640.

In the first semiconductor chip forming step S610, a plurality of first element regions are formed in a first substrate by block units.

In the second semiconductor chip forming step S620, a plurality of second element regions are formed in a second substrate by block units.

In the semiconductor chip bonding step S630, the first semiconductor chip is bonded to the second semiconductor chip.

In the substrate separation means forming step S640, a substrate separation means is formed between the blocks of the plurality of first element regions, which are formed in the first substrate or between the blocks of the plurality of second element regions, which are formed in the second substrate.

Meanwhile, in the substrate separation means forming step S640, in case that the substrate separation means is formed in all of the first substrate and the second substrate, the substrate separation means formed in the first substrate and the second substrate may be coupled to each other in an integrated body type or may be formed separately.

After the substrate separation means forming step S640, a post process step S650 including an antireflection film forming step that forms an antireflection film on an opposite side of the second insulation layer in the second substrate, a pad forming step for connection to an external device, a color filter forming step and a micro-lens forming step may be further included.

Meanwhile, the substrate separation means forming step S640 may be performed simultaneously to a process for etching the substrate to form a pad for connection to an external, or may be performed to form a trench by a reactive ion etching (RIE) etch or a wet etch using a plasma separately to the process for etching the substrate.

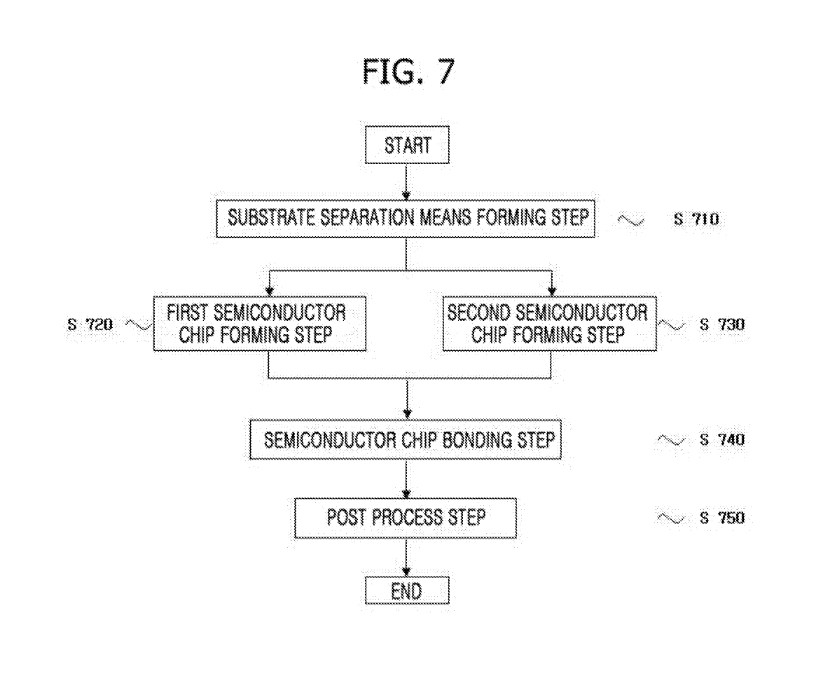

FIG. 7 is a flow chart illustrating a process flow of a method of manufacturing a substrate separation-type three-dimensional chip stacking image sensor in accordance with another embodiment of the present invention.

Referring to FIG. 7, a method of manufacturing a substrate separation-type three-dimensional chip stacking image sensor in accordance with another embodiment of the present invention includes a substrate separation means forming step S710, a first semiconductor chip forming step S720, a second semiconductor chip forming step S730 and a semiconductor chip bonding step S740.

In the substrate separation means forming step S710, the substrate separation means is formed between the blocks of the plurality of first element regions to be formed in the first substrate or between the blocks of the plurality of second element regions to be formed in the second substrate through the plasma etch or the wet etch.

In the first semiconductor chip forming step S720, the plurality of first element regions are formed in the first substrate by the block units.

In the second semiconductor chip forming step S730, the plurality of second element regions are formed in the second substrate by the block units.

In the semiconductor chip bonding step S740, the first semiconductor chip and the second semiconductor chip are bonded to each other.

After the semiconductor chip bonding step S740, a post process step S750 including an antireflection film forming step that forms an antireflection film on an opposite side of the second insulation layer in the second substrate, a pad forming step for connection to an external device, a color filter forming step and a micro-lens forming step may be further included.

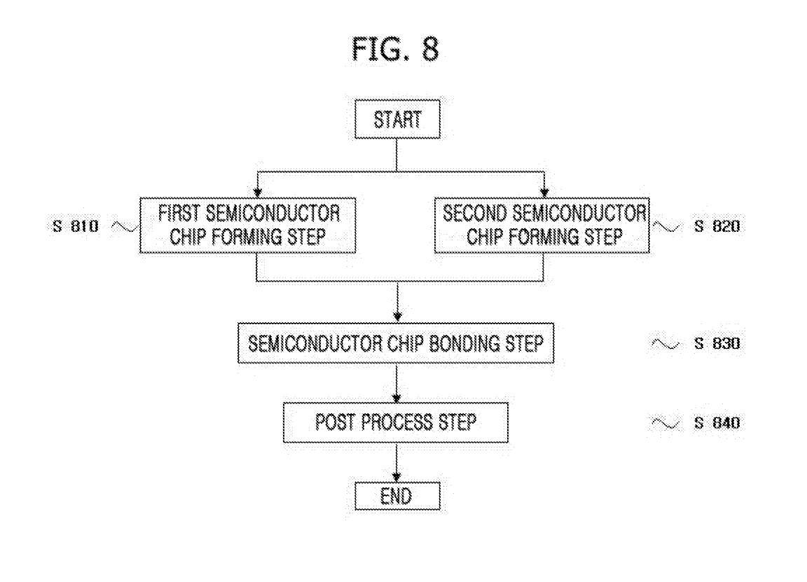

FIG. 8 is a flow chart illustrating a process flow of a method of manufacturing a substrate separation-type three-dimensional chip stacking image sensor in accordance with another embodiment of the present invention.

Referring to FIG. 8, a method of manufacturing a substrate separation-type three-dimensional chip stacking image sensor in accordance with another embodiment of the present invention includes a first semiconductor chip forming step S810, a second semiconductor chip forming step S820 and a semiconductor chip bonding step S830.

In the first semiconductor chip forming step S810, a plurality of element regions are formed in the first substrate by block units, and a substrate separation means is formed between the blocks of the plurality of first element regions.

In the second semiconductor chip forming step S820, a plurality of element regions are formed in the second substrate b block units, and a substrate separation means is formed between the blocks of the plurality of second element regions.

In the semiconductor chip bonding step 5830, the first semiconductor chip and the second semiconductor chip are bonded.

That is, in the embodiment shown in FIG. 8, since the substrate separation means forming step is included in the first semiconductor chip forming step S810 and the second semiconductor chip forming step S820, the embodiment shown in FIG. 6 is different from the embodiment shown in FIG. 8.

After the semiconductor chip bonding step S830, a post process step S840 including an antireflection film forming step that forms an antireflection film on an opposite side of the second insulation layer in the second substrate, a pad forming step for connection to an external device, a color filter forming step and a micro-lens forming step may be further included.

Meanwhile, methods of manufacturing a substrate separation-type three-dimensional chip stacking image sensor in accordance with another embodiment of the present invention shown in FIGS. 6 to 8 may further include a step for filling at least one conductive material selected among Titanium (Ti), Titanium Nitride (TIN), aluminum (Al) tungsten (W) or poly in a region where the substrate separation means is formed in the first semiconductor chip or the second semiconductor chip.

An external bias is applied and a potential of a peripheral region of the trench is adjusted by filling the conductive material in the region separated by the trench. Herein, it is preferable that the step for filling the conductive material is performed by a chemical vapor deposition (CVD) process, a physical vapor deposition (PVD) process or an electric plating process.

Also, methods of manufacturing a substrate separation-type three-dimensional chip stacking image sensor in accordance with another embodiment of the present invention shown in FIGS. 6 to 8 may further include a step for filling at least one insulation material selected among an oxide layer, a nitride layer or a photoresist in the region where the substrate separation means is formed. Like this, a planarization to non-etched other regions may be performed by filling the insulation material in the region separated by the trench.

Herein, it is preferable that the step for filling the insulation material is performed by the chemical vapor deposition (CVD) process.

Although various embodiments have been described for illustrative purposes, it will be apparent to those skilled in the art that various changes and modifications may be made without departing from the spirit and scope of the invention as defined in the following claims.

1. A substrate separation-type three-dimensional chip stacking image sensor, comprising;
a first semiconductor chip having a plurality of first element regions, which are formed in a first substrate by block units; and
a second semiconductor chip having a plurality of second element regions, which are formed in a second substrate by block units,
wherein the second semiconductor chip is stacked on the first semiconductor chip, and
wherein the second semiconductor chip further includes a substrate separation means that separates the plurality of second element regions formed in the second substrate by the block units.

2. A substrate separation-type three-dimensional chip stacking image sensor, comprising;
a first semiconductor chip having a plurality of first element regions, which are formed in a first substrate by block units; and
a second semiconductor chip having a plurality of second element regions, which are formed in a second substrate by block units,
wherein the second semiconductor chip is stacked on the first semiconductor chip, and
wherein the first semiconductor chip further includes a substrate separation means that separates the plurality of first element regions formed in the first substrate by the block units.

3. A substrate separation-type three-dimensional chip stacking image sensor, comprising;
a first semiconductor chip having a plurality of first element regions, which are formed in a first substrate by block units; and
a second semiconductor chip having a plurality of second element regions, which are formed in a second substrate by block units,
wherein the second semiconductor chip is stacked on the first semiconductor chip,
wherein the first semiconductor chip further includes a substrate separation means that separates the plurality of first element regions formed in the first substrate by the block units, and
wherein the second semiconductor chip further includes a substrate separation means that separates the plurality of second element regions formed in the second substrate by the block units.

4. The substrate separation-type three-dimensional chip stacking image sensor of claim 3, wherein the substrate separation means formed in the first semiconductor chip and the substrate separation means formed in the second semiconductor chip are coupled to be an integrated body type, or are formed separately.

5. The substrate separation-type three-dimensional chip stacking image sensor of claim 1, wherein the substrate separation means is a trench formed by a reactive ion etching (RIE) or a wet etch using a plasma.

6. The substrate separation-type three-dimensional chip stacking image sensor of claim 5, wherein a conductive material or an insulation material is filled in the substrate separation means.

7. The substrate separation-type three-dimensional chip stacking image sensor of claim 6, wherein the conductive material is at least one selected among titanium (Ti), Titanium nitride (TiN), aluminium (Al), tungsten (W) or poly.

8. The substrate separation-type three-dimensional chip stacking image sensor of claim 6, wherein the insulation material is at least one selected among an oxide layer, a nitride layer or a photoresist.

9. The substrate separation-type three-dimensional chip stacking image sensor of claim 5, wherein the substrate separation means has a vacant structure.

10. The substrate separation-type three-dimensional chip stacking image sensor of claim 1, wherein the substrate separation means formed in the first semiconductor chip separates only the first substrate, or separates the first substrate and a first insulation layer formed in the first substrate.

11. The substrate separation-type three-dimensional chip stacking image sensor of claim 2, wherein the substrate separation means formed in the second semiconductor chip separates only the second substrate, or separates the second substrate and a second insulation layer formed in the second substrate.

12. A method for manufacturing a substrate separation-type three-dimensional chip stacking image sensor, comprising steps of:
forming a first semiconductor chip that a plurality of first element regions are formed in a first substrate by block units;
forming a second semiconductor chip that a plurality of second element regions are formed in a second substrate by block units;
bonding the first semiconductor chip to the second semiconductor chip; and
forming a substrate separation means between blocks of the plurality of first element regions formed in the first semiconductor chip or between blocks of the plurality of second element regions formed in the second semiconductor chip.

13. A method for manufacturing a substrate separation-type three-dimensional chip stacking image sensor, comprising steps of:
forming a substrate separation means between blocks of a plurality of first element regions to be formed in a first substrate or between blocks of a plurality of second element regions to be formed in a second substrate through a plasma etch or a wet etch;
forming a first semiconductor chip that the plurality of first element regions are formed in the first substrate by block units;
forming a second semiconductor chip that the plurality of second element regions are formed in the second substrate by block units; and
bonding the first semiconductor chip to the second semiconductor chip.

14. A method for manufacturing a substrate separation-type three-dimensional chip stacking image sensor, comprising steps of:
forming a first semiconductor chip that a plurality of first element regions are formed in a first substrate by block units and a substrate separation means is formed between blocks of the plurality of first element regions;
forming a second semiconductor chip that a plurality of second element regions are formed in a second substrate by block units and a substrate separation means is formed between blocks of the plurality of second element regions; and
bonding the first semiconductor chip to the second semiconductor chip.

15. The method for manufacturing the substrate separation-type three-dimensional chip stacking image sensor of claim 12, further comprising steps of:
forming an antireflection film and an insulation layer;
forming a color filter; and
forming a micro-lens.

16. The method for manufacturing the substrate separation-type three-dimensional chip stacking image sensor of claim 12, wherein the step of forming the substrate separation means is simultaneously performed with a step of etching a substrate to form a pad for a connection with an external device.

17. The method for manufacturing the substrate separation-type three-dimensional chip stacking image sensor of claim 12, wherein the step of forming the substrate separation means forms a trench through a reactive ion etching (RIE) or a wet etch using a plasma separately to a step of etching a substrate to form a pad for a connection with an external device.

18. The method for manufacturing the substrate separation-type three-dimensional chip stacking image sensor of claim 12, further comprising step of:
filling at least one conductive material selected among titanium (Ti), titanium nitride (TiN), aluminium (Al), tungsten (W), or poly in a region where the substrate separation means is formed in the first semiconductor chip or the second semiconductor chip.

19. The method for manufacturing the substrate separation-type three-dimensional chip stacking image sensor of claim 12, further comprising step of:
filling at least one insulation material selected among an oxide layer, a nitride layer or a photoresist in a region where the substrate separation means is formed in the first semiconductor chip or the second semiconductor chip.

20. The method for manufacturing the substrate separation-type three-dimensional chip stacking image sensor of claim 18, wherein the step of filling the at least one conductive material includes filling the at least one conductive material through a chemical vapor deposition (CVD) process, a physical vapor deposition (PVD) process or an electric plating process.

21. The method for manufacturing the substrate separation-type three-dimensional chip stacking image sensor of claim 19, wherein the step of filling the at least one insulation material includes filling the at least one insulation material through a chemical vapor deposition (CVD) process.
